(19) United States
(12) Patent Application Publication
(10) Pub. No.: US 2025/0089509 A1
(43) Pub. Date: Mar. 13, 2025

(54) DISPLAY SUBSTRATE AND DISPLAY DEVICE

(71) Applicants: Chengdu BOE Optoelectronics Technology Co., Ltd., Sichuan Province (CN); BOE Technology Group Co., Ltd., Beijing (CN)

(72) Inventors: Xinxing GUAN, Beijing (CN); Shanshan BAI, Beijing (CN); Yuhao ZHANG, Beijing (CN)

(21) Appl. No.: 18/292,732

(22) PCT Filed: Aug. 27, 2021
(86) PCT No.: PCT/CN2021/115063

§ 371 Date: Jan. 26, 2024

(51) Int. Cl. H10K 59/35; H10K 59/122

(52) U.S. Cl. CPC H10K 59/353; H10K 59/122; H10K 59/352

(57) ABSTRACT

The present disclosure provides a display substrate and a display device. The display substrate comprises: a base substrate having a first display area and a second display area located on at least one side of the first display area, the transmittance of the first display area being greater than that of the second display area; a plurality of light-emitting components arranged in an array on the base substrate, the plurality of light-emitting components comprising a plurality of first light-emitting components located in the first display area and a plurality of second light-emitting components located in the second display area, the gap between each two adjacent first light-emitting components being greater than the gap between each two adjacent second light-emitting components.

The present application is a National Stage of International Application No. PCT/CN2021/115063, filed Aug. 27, 2021, the entire contents of which are incorporated by reference in the present application.

### TECHNICAL FIELD

The present disclosure relates to the field of a display technology, in particular to a display substrate and a display device.

### BACKGROUND

As a new display technology, the organic light emitting diode (OLED) has strong competitiveness in the new generation of displays due to its many advantages, such as active light emission, wide viewing angle, high contrast, fast response, low power consumption, foldable and flexible, etc., unmatched by other display technologies. Currently, OLED display devices have begun to replace traditional liquid crystal displays (LCDs) in the fields of flat panel displays such as mobile phones, computers, and digital cameras.

With the extensive development and application of OLED technology, the pursuit of “full screen” display with better visual experience has become one of the trends in the development of the current display technology. However, due to the restriction of the metal layer with the low transmittance in the device structure on the photo effect of the front camera, the further design optimization of the metal layer is particularly important.

### SUMMARY

Embodiments of the present disclosure provide a display substrate and a display device, and the specific solutions are as follows.

On the one hand, the embodiments of the present disclosure provide a display substrate, including: a base substrate including a first display region and a second display region on at least one side of the first display region; and transmittance of the first display region is greater than transmittance of the second display region; a plurality of light-emitting assemblies arranged in an array on the base substrate; the plurality of light-emitting assemblies includes a plurality of first light-emitting assemblies in the first display region, and a plurality of second light-emitting assemblies in the second display region; wherein a gap between two first light-emitting assemblies that are adjacent to each other is greater than a gap between two second light-emitting assemblies that are adjacent to each other; wherein the plurality of light-emitting assemblies includes cathodes provided with hollow structures in the first display region, and orthographic projections of the hollow structures on the base substrate overlap with an orthographic projection of at least part of gaps between the first light-emitting assemblies; and a cathode patterning material layer, at a light-emitting side of the plurality of light-emitting assemblies; wherein an orthographic projection of the cathode patterning material layer on the base substrate substantially coincides with the orthographic projections of the hollow structures.

In some embodiments, in the above mentioned display substrate provided by the embodiments of the present disclosure, the plurality of first light-emitting assemblies include first light-emitting devices with at least two colors, and the plurality of second light-emitting assemblies include second light-emitting devices with at least two colors; wherein the at least two colors of the first light-emitting devices are the same as the at least two colors of the second light-emitting devices; and a length of a light-emitting region of a first light-emitting device in a column direction is less than a length of a light-emitting region of a second light-emitting device with the same light-emitting color as the first light-emitting device in the column direction, and a width of the light-emitting region of the first light-emitting device in a row direction is less than or equal to a width of the light-emitting region of the second light-emitting device with the same light-emitting color as the first light-emitting device in the row direction.

In some embodiments, in the above mentioned display substrate provided by the embodiments of the present disclosure, ach of the plurality of light-emitting assembles includes one first light-emitting device with a first color, two first light-emitting devices with a second color, and one first light-emitting device with a third color; wherein a width of a light-emitting region of the first light-emitting device with the first color is substantially equal to a width of a light-emitting region of a second light-emitting device with the same light-emitting color as the first light-emitting device with the first color, and a width of a light-emitting region of the first light-emitting device with the third color is substantially equal to a width of a light-emitting region of a second light-emitting device with the same light-emitting color as the first light-emitting device with the third color; and widths of light-emitting regions of the two first light-emitting devices with the second color are less than a width of light-emitting region of a second light-emitting device with the same light-emitting color as the two first light-emitting devices with the second color.

In some embodiments, in the above mentioned display substrate provided by the embodiments of the present disclosure, geometric centers of the light-emitting regions of first light-emitting devices in each of the plurality of first light-emitting assemblies are staggered in the row direction and/or the column direction.

In some embodiments, in the above mentioned display substrate provided by the embodiments of the present disclosure, in the first light-emitting assembly, the light-emitting regions of the two first light-emitting devices with the second color are staggered in the row direction and the column direction; the light-emitting region of the first light-emitting device with the third color partially overlaps with a light-emitting region of one of the two first light-emitting devices with the second color in the row direction, and partially overlaps with a light-emitting region of the other one of the two first light-emitting devices with the second color in the column direction; and the light-emitting region of the first light-emitting device with the first color partially overlaps with the light-emitting region of one of the two first light-emitting devices with the second color in the row direction, and is arranged in a staggered manner with the light-emitting region of the other one of the two first light-emitting devices with the second color and the light-emitting region of the first light-emitting device with the third color in the column direction.

In some embodiments, in the above mentioned display substrate provided by the embodiments of the present disclosure, the plurality of first light-emitting assemblies include first light-emitting devices with at least two colors, and the plurality of second light-emitting assemblies include second light-emitting devices with at least two colors; the at least two colors of the first light-emitting devices are the same as the at least two colors of the second light-emitting devices; a length of a light-emitting region of a first light-emitting device in a column direction is less than a length of a light-emitting region of a second light-emitting device with the same light-emitting color as the first light-emitting device in the column direction, and a width of the light-emitting region of the first light-emitting device in a row direction is substantially equal to a width of the light-emitting region of the second light-emitting device with the same light-emitting color as the first light-emitting device in the row direction; or a length of a light-emitting region of a first light-emitting device in a column direction is substantially equal to a length of a light-emitting region of a second light-emitting device with the same light-emitting color as the first light-emitting device in the column direction, and a width of the light-emitting region of the first light-emitting device in a row direction is less than a width of the light-emitting region of the second light-emitting device with the same light-emitting color as the first light-emitting device in the row direction.

In some embodiments, in the above mentioned display substrate provided by the embodiments of the present disclosure, each of the plurality of light-emitting assemblies includes one first light-emitting device with a first color, two first light-emitting devices with a second color, and one first light-emitting device with a third color; a length of a light-emitting region of the first light-emitting device with the first color is less than a length of a light-emitting region of a second light-emitting device with the same light-emitting color as the first light-emitting device with the first color; and a width of the light-emitting region of the first light-emitting device with the first color is substantially equal to a width of the light-emitting region of the second light-emitting device with the same light-emitting color as the first light-emitting device with the first color; and lengths of light-emitting regions of the two first light-emitting devices with the second color are substantially equal to a length of a light-emitting region of a second light-emitting device with the same light-emitting color as the two first light-emitting devices with the second color, and a length of a light-emitting region of the first light-emitting device with the third color is substantially equal to a length of a light-emitting region of a second light-emitting device with the same light-emitting color as the first light-emitting device with the third color; and widths of the light-emitting regions of the two first light-emitting devices with the second color are less than a width of the light-emitting region of the second light-emitting device with the same light-emitting color as the two first light-emitting devices with the second color, and a width of the light-emitting region of the first light-emitting device with the third color is less than a width of a light-emitting region of the second light-emitting device with the same light-emitting color as the first light-emitting device with the third color.

In some embodiments, in the above mentioned display substrate provided by the embodiments of the present disclosure, in the first light-emitting assembly, a geometric center of the light-emitting region of the first light-emitting device with the first color and a geometric center of the light-emitting region of the first light-emitting device with the third color are located at the same straight line along the row direction, and the geometric center of the light-emitting region of the first light-emitting device with the first color and geometric centers of the light-emitting regions of the two first light-emitting devices with the second color are staggered in the row direction; and the geometric centers of the light-emitting regions of the first light-emitting devices with the second color are located at the same straight line along the column direction, the geometric center of the light-emitting region of the first light-emitting device with the first color, the geometric centers of the light-emitting regions of the first light-emitting devices with the second color and the geometric center of the light-emitting region of the first light-emitting device with the third color are staggered in the column direction.

In some embodiments, in the above mentioned display substrate provided by the embodiments of the present disclosure, in the first light-emitting assembly: the light-emitting regions of the two first light-emitting devices with the second color are staggered in the row direction and overlapped in the column direction; the light-emitting region of the first light-emitting device with the first color, the light-emitting regions of the two first light-emitting devices with the second color and the light-emitting region of the first light-emitting device with the third color are staggered in the column direction, and the light-emitting region of the first light-emitting device with the first color is between the light-emitting regions of the two first light-emitting devices with the second color and the light-emitting region of the first light-emitting device with the third color; and the light-emitting region of the first light-emitting device with the first color and the light-emitting region of the first light-emitting device with the third color partially overlap with the light-emitting regions of the two first light-emitting devices with the second color in the row direction.

In some embodiments, in the above mentioned display substrate provided by the embodiments of the present disclosure, a width of a light-emitting material layer of the first light-emitting device with the first color in the row direction is substantially equal to a width of an anode in the row direction; an orthographic projection of a side edge of a light-emitting material layer of the first light-emitting device with the second color adjacent to and near the light-emitting material layer of the first light-emitting device with the first color on the base substrate substantially coincides with an orthographic projection of a side edge of an anode of the first light-emitting device with the second color; and an orthographic projection of a side edge, adjacent to and near the light-emitting material layer of the first light-emitting device with the first color, of a light-emitting material layer of the first light-emitting device with the third color on the base substrate substantially coincides with the orthographic projection of the side edge of the anode of the first light-emitting device with the second color.

In some embodiments, in the above mentioned display substrate provided by the embodiments of the present disclosure, a geometric center of a light-emitting material layer of the first light-emitting device with the first color and a geometric center of a cathode patterning material layer corresponding to the first light-emitting device with the first color are located at the same straight line along the row direction.

In some embodiments, in the above mentioned display substrate provided by the embodiments of the present disclosure, the first color is red, the second color is green, and the third color is blue.

In some embodiments, in the above mentioned display substrate provided by the embodiments of the present disclosure, a density of first light-emitting devices in the first display region is the same as a density of second light-emitting devices in the second display region.

In some embodiments, in the above mentioned display substrate provided by the embodiments of the present disclosure, an area of an anode of the first light-emitting device is less than an area of an anode of the second light-emitting device with the same light-emitting color.

In some embodiments, in the above mentioned display substrate provided by the embodiments of the present disclosure, the plurality of first light-emitting assemblies include first light-emitting devices with at least two colors, and the plurality of second light-emitting assemblies include second light-emitting devices with at least two colors; wherein the at least two colors of the first light-emitting devices are same as the at least two colors of the second light-emitting devices; and a density of the first light-emitting devices in the first display region is less than a density of the second light-emitting devices in the second display region.

In some embodiments, in the above mentioned display substrate provided by the embodiments of the present disclosure, a length of a light-emitting region of a first light-emitting device in a column direction is equal to a length of a light-emitting region of a second light-emitting device with the same light-emitting color as the first light-emitting device in the column direction, and a width of the light-emitting region of the first light-emitting device in a row direction is equal to a width of the light-emitting region of the second light-emitting device with the same light-emitting color as the first light-emitting device in the row direction.

In some embodiments, the above mentioned display substrate provided by the embodiments of the present disclosure further includes: a pixel definition layer between a layer where anodes of the first light-emitting devices are located and a light-emitting material layer of the first light-emitting devices; the pixel definition layer includes a plurality of first pixel openings in the first display region and a plurality of second pixel openings in the second display region; the first pixel openings at least partially expose the anodes of the first light-emitting devices, and the second pixel openings at least partially expose anodes of the second light-emitting devices; and the first pixel openings are light-emitting regions of the first light-emitting devices, and the second pixel openings are light-emitting regions of the second light-emitting devices.

In some embodiments, in the above mentioned display substrate provided by the embodiments of the present disclosure, an area of the light-emitting material layer in the first light-emitting devices is substantially equal to an area of the light-emitting material layer in the second light-emitting devices with the same light-emitting color as the first light-emitting devices.

In some embodiments, in the above mentioned display substrate provided by the embodiments of the present disclosure, geometric centers of first light-emitting assemblies in one row are located at the same straight line, and geometric centers of first light-emitting assemblies in one column are located at the same straight line.

In some embodiments, in the above mentioned display substrate provided by the embodiments of the present disclosure, first light-emitting assemblies in odd-numbered rows and first light-emitting assemblies in even-numbered rows are arranged staggered in a column direction.

In some embodiments, in the above mentioned display substrate provided by the embodiments of the present disclosure, first light-emitting assemblies in all odd-numbered rows are arranged aligned in the column direction, and first light-emitting assemblies in all even-numbered rows are arranged aligned in the column direction.

In some embodiments, in the above mentioned display substrate provided by the embodiments of the present disclosure, a geometric center of a cathode patterning material layer and a geometric center of a first light-emitting assembly located at a row where the cathode patterning material layer is located are arranged at the same straight line, and the geometric center of the cathode patterning material layer and a geometric center of a first light-emitting assembly located at a column where the cathode patterning material layer is located are arranged at the same straight line.

In some embodiments, in the above mentioned display substrate provided by the embodiments of the present disclosure, orthographic projections of the cathode patterning material layers on the base substrate approximately coincides with orthographic projections of gaps between all the first light-emitting assemblies.

In some embodiments, in the above mentioned display substrate provided by the embodiments of the present disclosure, at any one of the gaps between all the first light-emitting assemblies, the orthographic projection of the cathode patterning material layer on the base substrate is a square or an ellipse.

On the other hand, the embodiments of the present disclosure provide a display device, including a light extraction module, and the above mentioned display substrate provided by the embodiments of the present disclosure; and the light extraction module is in the first display region.

### BRIEF DESCRIPTION OF FIGURES

FIG. 1 is a schematic structural diagram of a display device provided by an embodiment of the present disclosure.

FIG. 2 is a partially enlarged schematic diagram of the first display region FDC shown in FIG. 1.

FIG. 3 is a partially enlarged schematic diagram of the second display region AA shown in FIG. 1.

FIG. 4 is an enlarged schematic diagram along the first light-emitting assembly in FIG. 2.

FIG. 5 is the schematic cross-sectional structure diagram along line 1-11 in FIG. 2.

FIG. 6 is a schematic cross-sectional structure diagram along line III-IV in FIG. 3.

FIG. 7 is another partially enlarged schematic diagram of the first display region FDC shown in FIG. 1.

FIG. 8 is another partially enlarged schematic diagram of the first display region FDC shown in FIG. 1.

FIG. 9 is an enlarged schematic diagram along the first light-emitting assembly in FIG. 7.

FIG. 10 is another partially enlarged schematic diagram of the first display region FDC shown in FIG. 1.

### DETAILED DESCRIPTION

In order to make the purpose, technical solutions and advantages of the embodiments of the present disclosure clearer, the technical solutions of the embodiments of the present disclosure will be clearly and completely described below in conjunction with drawings of the embodiments of the present disclosure. It should be noted that that the size and shape of each figure in the drawings do not reflect the true scale, but are only intended to illustrate the present disclosure. And the same or similar reference numerals represent the same or similar elements or elements having the same or similar functions throughout.

Unless otherwise defined, technical or scientific terms used in the present disclosure shall have the ordinary meanings as understood by those with ordinary skills in the art to which the present disclosure belongs. Words “first”, “second” and similar words used in the present disclosure do not indicate any order, quantity or importance, but are only used to distinguish different assemblies. Word “comprise” or “include” or other similar words mean that the element or item appearing before the word encompasses the element or item listed after the word and its equivalents, but does not exclude other elements or items. Word “connecting” or “connected” or similar words are not limited to physical or mechanical connections, but may include electrical connections, whether direct or indirect. Words “upper”, “lower”, “left”, “right”, etc., are merely used to indicate a relative position relation, which may also change accordingly when an absolute position of a described object changes.

With the rapid development of display technology, not only the appearance of the display screen is required to be beautiful, but also to give users a better visual experience. Major manufacturers have begun to increase the screen-to-body ratio in display products, making the full screen a new point of competition. Full display with camera (FDC) technology refers to a technical solution that cancels the camera hole of the front camera on the display screen and builds the front camera under the display screen. Compared with notch screens and water drop screens currently on the market, it has realized a true full screen without holes, so that it can bring a sense of impact in terms of visual and use experience to a certain extent without affecting the high screen-to-body ratio.

In order to improve the imaging quality, the transmittance of the FDC region is required to be relatively high. At present, the implementation of the full display with camera technology still has constraints such as the cathode affecting the transmittance of the FDC region. In order to improve the transmittance of the FDC region, a cathode patterning technology (CPM) has emerged in the related art. Before the cathode evaporation, this technology uses a metal mask (i.e. FMM) to deposit the cathode patterning material with high transmittance at part of the gaps between the light-emitting assemblies (including red, green and blue light-emitting devices), and then uses an open mask to evaporate the cathode material. Since the region provided with the cathode patterning material can inhibit the deposition of the cathode material, the cathode pattern can be realized, so that the transmittance of the region without cathode in the FDC region is higher, thereby improving the overall transmittance of the FDC region.

However, in order to ensure that the FMM used for making the cathode patterning material layer is subjected to the uniform force when stretching, the opening of the FMM needs to be set in a regular shape (such as a square, a regular polygon, etc.). In the related art, the aperture ratio and arrangement of the light-emitting devices in the FDC region are the same as those in the AA region, and in order to ensure that the lifespans of the red light device, green light device and blue light device are roughly equal to prevent color shift and other defects, the aperture ratio of the blue light device, the aperture ratio of the green light device, and the aperture ratio of the red light device are usually set to decrease successively. Therefore, the sizes of the gaps between the anodes of light-emitting devices with different color are inconsistent, so that the gaps between the light-emitting assemblies cannot be fully utilized to set the opening of the FMM of the regular shapes, which results in limited improvement of the transmittance of the FDC region by the CPM technology.

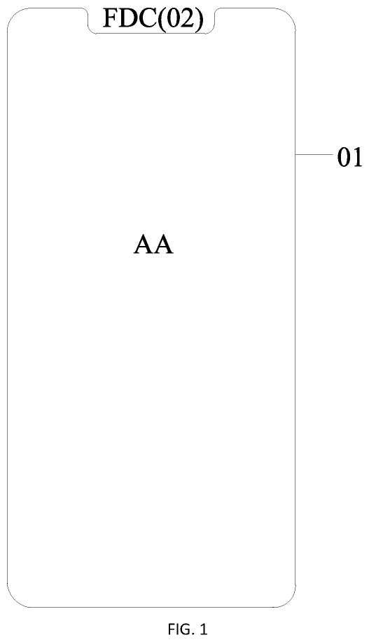

In order to improve the above-mentioned technical problems in related art, embodiments of the present disclosure provide a display substrate, as shown in FIG. 1 to FIG. 6, including: a base substrate 101, including: a first display region FDC and a second display region AA on at least one side of the first display region FDC; wherein transmittance of the first display region FDC is greater than transmittance of the second display region AA; a plurality of light-emitting assemblies 102 arranged in an array on the base substrate 101, wherein the plurality of light-emitting assemblies 102 include a plurality of first light-emitting assemblies P1 in the first display region FDC, and a plurality of second light-emitting assemblies P2 n the second display region AA, wherein a gap between two first light-emitting assemblies P1 that are adjacent to each other is greater than a gap between two second light-emitting assemblies P2 that are adjacent to each other; wherein the plurality of light-emitting assemblies 102 include cathodes C, and the cathodes C have hollow structures K in the first display region FDC, and orthographic projections of the hollow structures K on the base substrate 101 overlap with an orthographic projection of at least part of gaps between the plurality of first light-emitting assemblies 102; a cathode patterning material layer 103 at a light-emitting side of the light-emitting assemblies 102, and an orthographic projection of the cathode patterning material layer 103 on the base substrate 101 substantially coincides with the orthographic projections of the hollow structures K.

In the above display substrate provided by the embodiments of the present disclosure, by setting gaps between the first light-emitting assemblies P1 in the first display region FDC to be larger than gaps between the second light-emitting assemblies P2 in the second display region AA, it is beneficial to from a cathode patterning material layer 103 with a regular shape in the larger gaps between the first light-emitting assemblies P1. Thus, compared with the related art in which the gaps between the first light-emitting assemblies P1 in the first display region FDC is equal to the gaps of the second light-emitting assemblies P2 in the second display region AA, the transmittance of the first display region FDC can effectively improve.

It should be noted that, in the embodiments provided in the present disclosure, due to the limitation of process conditions or the influence of other factors such as measurement, “substantially” may be completely the same, or there may be some deviations, so the “substantially” relationship between the characteristics mentioned in the present disclosure falls within the claimed scope of the present disclosure as long as an error (for example, with a fluctuation of 10% up and down) is allowed.

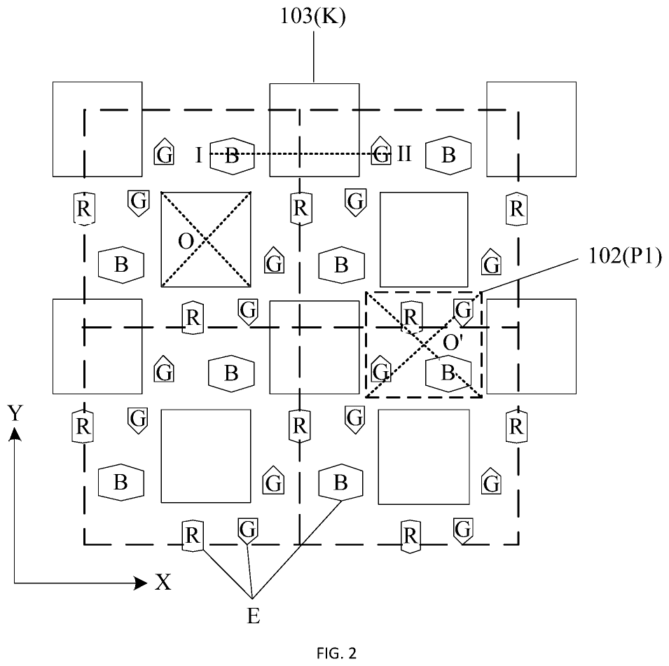

In some embodiments, in the above-mentioned display substrate provided by the embodiments of the present disclosure, as shown in FIG. 2 to FIG. 6, the plurality of first light-emitting assemblies P1 include first light-emitting devices 21 with at least two colors, the plurality of second light-emitting assemblies P2 include second light-emitting devices 22 with at least two colors, and the at least two colors of the first light-emitting devices 21 are the same as at least two colors of the second light-emitting devices 22. Optionally, the first light-emitting device 21 and the second light-emitting device 22 may respectively include light-emitting devices with three colors of red, green and blue (RGB). In some embodiments, a length of a light-emitting region E of the first light-emitting device 21 in a column direction Y is less than a length of a light-emitting region E of the second light-emitting device 22 with the same light-emitting color as the first light-emitting device 21 in the column direction Y; and a width of the light-emitting region E of the first light-emitting device 21 in a row direction X is less than or equal to a width of the light-emitting region E of the second light-emitting device 22 with the same light-emitting color as the first light-emitting device 21 in the row direction X.

Compared with the light-emitting regions E of the second light-emitting devices 22 in the second display region AA, by reducing the lengths and/or widths of the light-emitting regions E in the first light-emitting devices 21, there is an enough space for arranging the cathode patterning material layer 103, so as to effectively improve the transmittance of the first display region FDC.

In some embodiments, in the above-mentioned display substrate provided by the embodiments of the present disclosure, a light-emitting assembly 102 includes one first light-emitting device 21 with a first color, two first light-emitting devices 21 with a second color, and one first light-emitting device 21 with a third color. A width of a light-emitting region E of the first light-emitting device 21 with the first color is substantially equal to a width of a light-emitting region E of a second light-emitting device 22 with the same light-emitting color, and a width of a light-emitting region E of the first light-emitting device 21 with the third color is substantially equal to a width of a light-emitting region E of a second light-emitting device 22 with the same light-emitting color; and widths of light-emitting regions E of the two first light-emitting devices 21 with the second color are less than a width of a light-emitting region E of a second light-emitting device 22 with the same light-emitting color.

It can be seen from the above that, compared with the light-emitting region E of the second light-emitting device 22 in the second display region AA, the light-emitting region E of the first light-emitting device 21 with the first color and the light-emitting region E of the first light-emitting device 21 with the third color in the first display region FDC decrease in length and remain unchanged in width, and the light-emitting regions E of the first light-emitting devices 21 with the second color decrease in length and width. This arrangement can not only increase the space for arranging the cathode patterning material layer 103, but also improve the transmittance. Moreover, the lifespans of the light-emitting regions E of the first light-emitting devices 21 of the three colors can be equalized, which is beneficial to improve the quality of the display picture.

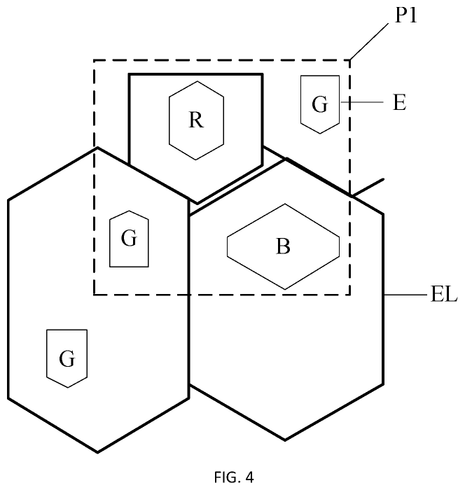

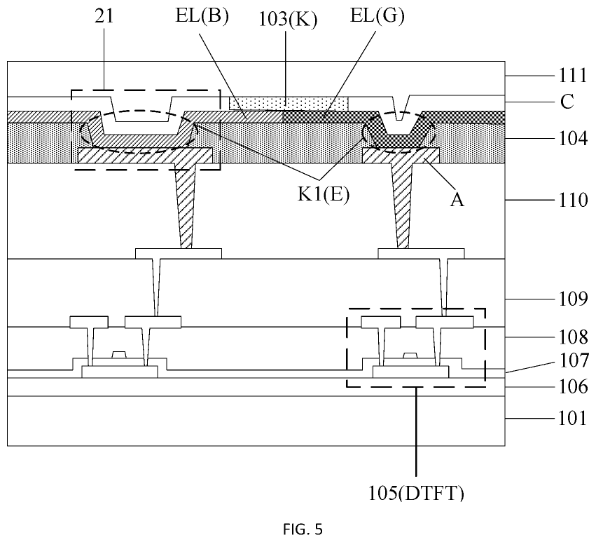

In some embodiments, in the above-mentioned display substrate provided by the embodiments of the present disclosure, as shown in FIG. 2, FIG. 4 and FIG. 5, geometric centers of light-emitting regions E of first light-emitting devices 21 of the light-emitting assembly 102 in the row direction X and the column direction Y are staggered, which can effectively increase the gaps between the first light-emitting assemblies 102 and conducive to form the cathode patterning material layer 103 with a regular shape at the larger gap, so as to greatly improve the transmittance of the first display region FDC.

In some embodiments, in the above-mentioned display substrate provided by the embodiments of the present disclosure, in order to balance the transmittance and the display effect, as shown in FIG. 2, FIG. 4 and FIG. 5, in the first light-emitting assembly P1: light-emitting regions E of two first light-emitting devices 21 with the second color can be arranged staggered in the row direction X and the column direction Y; the light-emitting region E of the light-emitting device 21 with the third color can partially overlap with the light-emitting region E of one of the two first light-emitting devices 21 with the second color in the row direction X, and partially overlap with the light-emitting region E of the other one of the two first light-emitting devices 21 with the second color in the column direction Y; and the light-emitting region E of the first light-emitting device 21 with the first color can partially overlap with the light-emitting region E of one of the two first light-emitting devices 21 with the second color in the row direction X, and can be arranged in a staggered manner with the light-emitting region E of the other one of the two first light-emitting devices 21 with the second color and the light-emitting region E of the first light-emitting device 21 with the third color in the column direction Y.

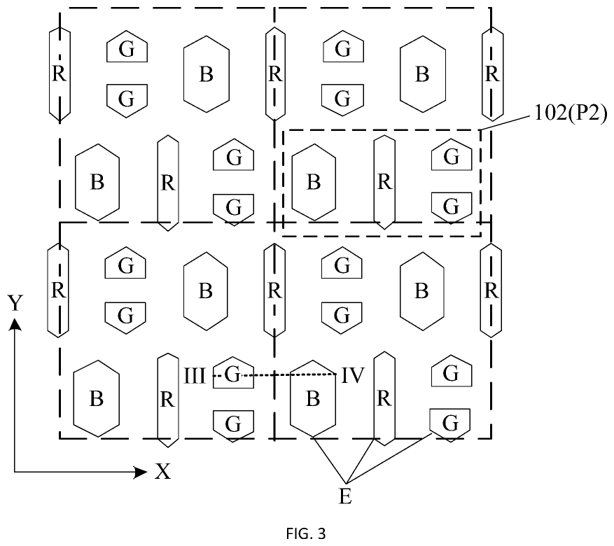

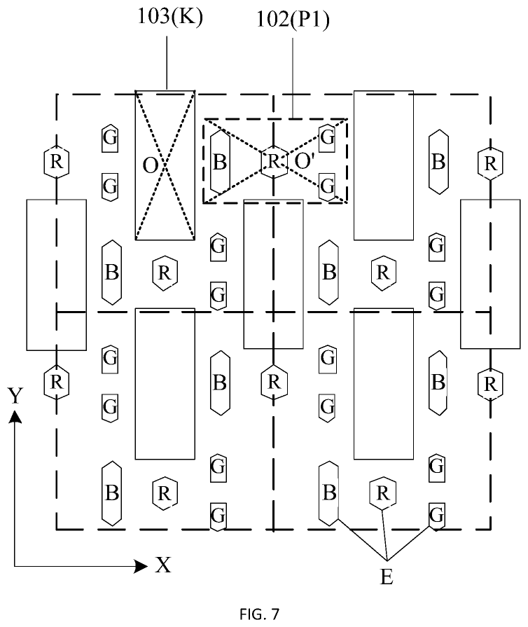

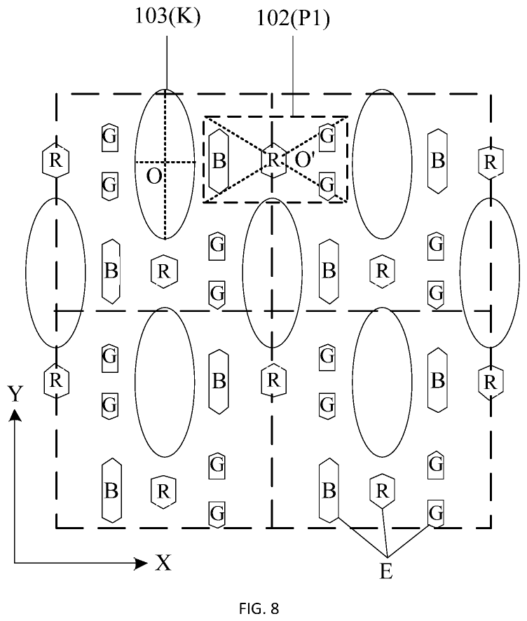

In some embodiments, in the above-mentioned display substrate provided by the embodiments of the present disclosure, as shown in FIG. 3, FIG. 7 and FIG. 8, it is also possible to set that the length of the light-emitting region E of the first light-emitting device 21 in the column direction Y is less than the length of the light-emitting region E of the second light-emitting device 22 with the same light-emitting color in the column direction Y, and the width of the light-emitting region E of the first light-emitting device 21 in the row direction X is substantially equal to the width of the light-emitting region E of the second light-emitting device 22 with the same light-emitting color in the row direction X; or, the length of the light-emitting region E of the first light-emitting device 21 in the column direction Y is substantially equal to the length of the light-emitting region E of the second light-emitting device 22 with the same light-emitting color in the column direction Y, and the width of the light-emitting region E of the first light-emitting device 21 in the row direction X is less than the width of the light-emitting region E of the second light-emitting device 22 with the same light-emitting color in the row direction X.

Compared with the light-emitting region E of the second light-emitting device 22 in the second display region AA, by reducing the length or width of the light-emitting region E of the first light-emitting device 21 in the first display region FDC, there is an enough space for arranging the cathode patterning material layer 103, so as to effectively improve the transmittance of the first display region FDC.

In some embodiments, in the above-mentioned display substrate provided by the embodiments of the present disclosure, as shown in FIG. 3, FIG. 7 and FIG. 8, the light-emitting assembly 102 may include one first light-emitting device 21 with the first color, two first light-emitting devices 21 with the second color, and one first light-emitting device with the third color. The length of the light-emitting region E of the first light-emitting device 21 with the first color is less than the length of the light-emitting region E of the second light-emitting device 22 with the same light-emitting color; the width of the light-emitting region E of the first light-emitting device 21 with the first color is substantially equal to the width of the light-emitting region E of the second light-emitting device 22 with the same light-emitting color; the lengths of the light-emitting regions E of the first light-emitting devices 21 with the second color are substantially equal to the length of the light-emitting region E of the second light-emitting device 22 with the same light-emitting color, and the length of the light-emitting region E of the first light-emitting device 21 with the third color is substantially equal to the length of the light-emitting region E of the second light-emitting device 22 with the same light-emitting color; and the widths of the light-emitting regions E of the first light-emitting devices 21 with the second color are less than the width of the light-emitting region E of the second light-emitting device 22 with the same light-emitting color, and the width of the light-emitting region E of the first light-emitting device 21 with the third color is less than the width of the light-emitting region E of the second light-emitting device 22 with the same light-emitting color.

It can be seen from the above that, compared with the light-emitting region E of the second light-emitting device 22 in the second display region AA, the light-emitting region E of the first light-emitting device 21 with the first color in the first display region FDC decreases in length and remains unchanged in width, and the light-emitting regions E of the first light-emitting devices 21 with the second color and the light-emitting region E of the first light-emitting device 21 with the third color decrease in width and remain unchanged in length. This arrangement can also increase the space for arranging the cathode patterning material layer 103 to improve the transmittance. Moreover, the lifespan of the light-emitting regions E of the first light-emitting devices 21 of the three colors can be equalized, which is beneficial to improve the quality of the display picture.

In some embodiments, in the above-mentioned display substrate provided by the embodiments of the present disclosure, as shown in FIG. 7 to FIG. 9, in the first light-emitting assembly P1: a geometric center of the light-emitting region E of the first light-emitting device 21 with the first color and a geometric center of the light-emitting region E of the first light-emitting device 21 with the third color may be arranged at the same straight line along the row direction X, and the geometric center of the light-emitting region E of the first light-emitting device 21 with the first color and geometric centers of the light-emitting regions E of the two first light-emitting devices 21 with the second color are staggered in the row direction X; the geometric centers of the light-emitting regions E of the two first light-emitting devices 21 with the second color can be located at the same straight line along the column direction Y; and the geometric center of the light-emitting region E of the first light-emitting device 21 with first color, the geometric centers of the light-emitting regions E of the first light-emitting devices 21 with the second color, and the geometric center of the light-emitting region E of the first light-emitting device 21 with the third color are staggered in the column direction Y. The arrangement of the first light-emitting devices 21 in the above-mentioned first light-emitting assemblies 102 can effectively increase the gaps between the first light-emitting assemblies 102, which is conducive to forming a cathode patterning material layer 103 with a regular shape at the larger gap, and greatly improve the transmittance of the first display region FDC.

In some embodiments, in the above-mentioned display substrate provided by the embodiments of the present disclosure, in order to balance the transmittance and the display effect, as shown in FIGS. 7 to 9, in the first light-emitting assembly P1: the light-emitting regions E of the two first light-emitting devices 21 with the second color can be arranged staggered in the row direction X and overlapped in the column direction Y; the light-emitting region E of the first light-emitting device 21 with the first color, the light-emitting regions E of the first light-emitting devices 21 with second color and the light-emitting region E of the first light-emitting device 21 with the third color can be arranged staggered in the column direction Y, and the light-emitting region E of the first light-emitting device 21 with the first color can be located between the light-emitting regions E of the first light-emitting devices 21 with the second color and the light-emitting region E of the first light-emitting device 21 with the third color; the light-emitting region E of the first light-emitting device 21 with the first color and the light-emitting region E of the first light-emitting device 21 with the third color may partially overlap with the light-emitting regions E of the two first light-emitting devices 21 with the second color in the row direction X.

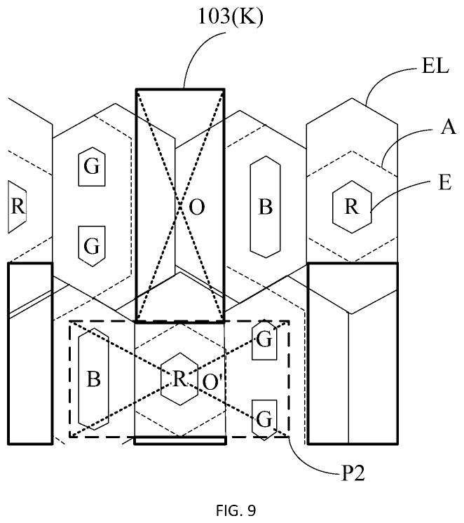

In some embodiments, in the above-mentioned display substrate provided by the embodiments of the present disclosure, as shown in FIG. 9, a width of a light-emitting material layer EL of the first light-emitting device 21 with the first color in the row direction X is substantially equal to a width of an anode A in the row direction X; an orthographic projection of a side edge, adjacent to the first light-emitting device 21 with the first color, of a light-emitting material layer EL of the first light-emitting device 21 with the second color on the base substrate 101 substantially coincides with an orthographic projection of a side edge of an anode A of the first light-emitting device 21 with the second color; an orthographic projection of a side edge, adjacent to the first light-emitting device 21 with the first color, of a light-emitting material layer EL of the first light-emitting device with the third color on the base substrate 101 substantially coincides with the orthographic projection of the side edge of the anode A of the first light-emitting device 21 with the second color.

In this way, on the basis of ensuring that the light-emitting regions E of light-emitting devices with the three-color meet the lifespan requirements, the gap between the adjacent first light-emitting devices 21 with the first color in the column direction Y can be increased, and the gap between the first light-emitting device 21 with the second color and the first light-emitting device 21 with the third color in the row direction X can be increased, so that the gap space enclosed by two first light-emitting devices 21 with the first color, one first light-emitting device 21 with the second color and one first light-emitting device 21 with the third color is larger, and the cathode patterning material layer 103 can be disposed in this space, thereby improving the transmittance of the first display region FDC.

In some embodiments, in the above-mentioned display substrate provided by the embodiments of the present disclosure, as shown in FIG. 9, the geometric center of the light-emitting material layer EL of the first light-emitting device 21 with the first color and a geometric center O of the cathode patterning material layer 103 corresponding to the first light-emitting device 21 with the first color can be located at the same straight line along the row direction X, so that the cathode patterning material layer 103 with a regular shape can be arranged based on the geometric center of the light-emitting material layer EL of the first light-emitting device 21 with the first color.

In some embodiments, in the above-mentioned display substrate provided by the embodiments of the present disclosure, the first color is red, the second color is green, and the third color is blue. As such, after reducing the light-emitting regions E of the first light-emitting devices 21 with different colors in the row direction X and/or the column direction Y, the requirement of roughly equal lifespans can still be met. Of course, in the specific implementation, the first color, the second color and the third color can also be other colors, as long as the lifespan decay rates of the first light-emitting device 21 with the first color, the first light-emitting device 21 with the second color and the first light-emitting device 21 with the third color increase sequentially.

In some embodiments, in the above-mentioned display substrate provided by the embodiments of the present disclosure, as shown in FIG. 2, FIG. 3, FIG. 7 and FIG. 8, the density (i.e. PPI) of the first light-emitting devices 21 in the first display region FDC may be the same as the density of the second light-emitting devices 22 in the second display region AA, so as to improve the overall display effect of the display picture.

In some embodiments, in the display substrate provided by the embodiments of the present disclosure, since at least one of the length and width of the light-emitting region E of the first light-emitting device 21 is less than a length of a corresponding side edge of the light-emitting region E of the second light-emitting device 22, a size of an anode A under the first light-emitting device 21 can be appropriately reduced, so that an area of the anode A of the first light-emitting device 21 is less than an area of an anode A of the second light-emitting device 22 with the same light-emitting color, thereby further improving the transmittance of the first display region FDC.

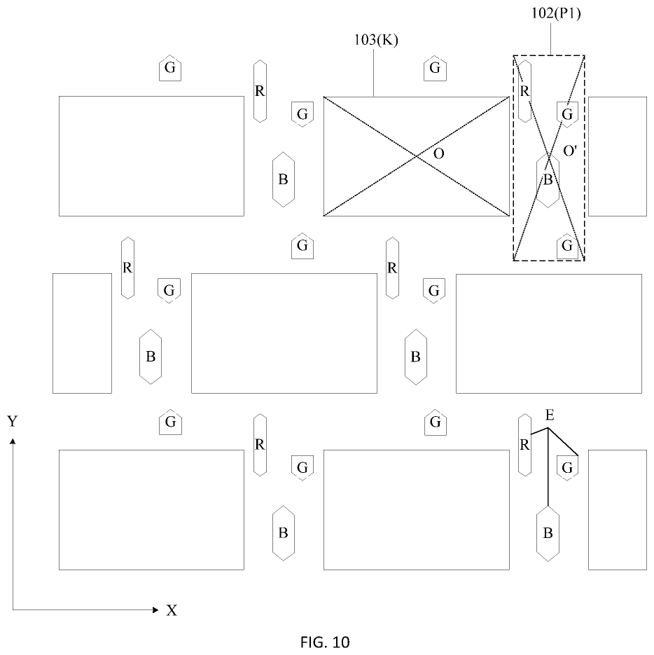

In some embodiments, in the above-mentioned display substrate provided by the embodiments of the present disclosure, as shown in FIG. 3 and FIG. 10, the density of the first light-emitting devices 21 in the first display region FDC is less than the density of the second light-emitting devices 22 in the second display region AA, which can also increase the transmittance of the first display region FDC, but will reduce the display effect to a certain extent.

In some embodiments, the density of the second light-emitting devices 22 in the second display region AA may be an integer multiple of the density of the first light-emitting devices 21 in the first display region FDC, so as to facilitate setting a cathode patterning material layer 103 with a larger area and a regular shape, and further improve the transmittance of the first display region FDC.

In some embodiments, when the density of the first light-emitting devices 21 in the first display region FDC is less than the density of the second light-emitting devices 22 in the second display region AA, the length of the light-emitting region E of the first light-emitting devices 21 in the column direction Y can be equal to the length of the light-emitting region E of the second light-emitting device 22 with the same light-emitting color in the column direction Y, and the width of the light-emitting region E of the first light-emitting device 21 in the row direction X can be equal to the width of the light-emitting region of the second light-emitting device 22 with the same light-emitting color in the row direction X. That is to say, when the density of the first light-emitting devices 21 in the first display region FDC is less than the density of the second light-emitting devices 22 in the second display region AA, the size of the first light-emitting devices 21 and the size of the second light-emitting devices 22 are the same, which facilitates the unification of the process parameters of the first light-emitting devices 21 and the second light-emitting devices 22, and improves the efficiency of mass production.

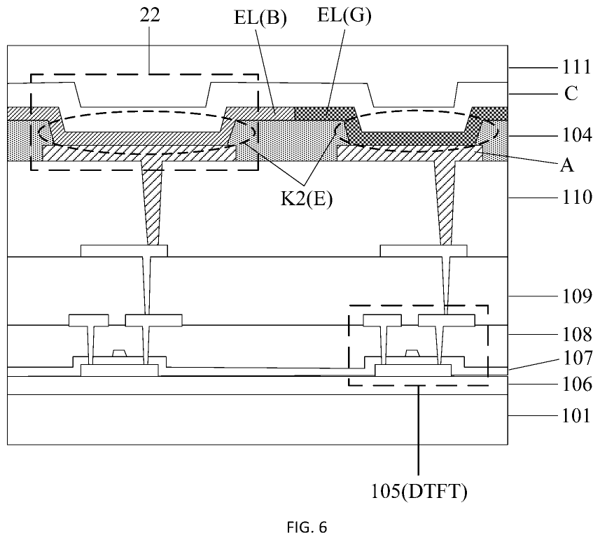

In some embodiments, the above-mentioned display substrate provided by the embodiments of the present disclosure, as shown in FIG. 5 and FIG. 6, further includes: a pixel definition layer 104 between a layer where anodes A of the first light-emitting devices 21 is located and the light-emitting material layer EL of the first light-emitting device 21, and the pixel definition layer 104 includes a plurality of first pixel openings K1 located in the first display region FDC and a plurality of second pixel openings K2 located in the second display region AA. The first pixel openings K1 at least partially expose the anodes A of the first light-emitting devices 21, and the second pixel openings K2 at least partially expose anodes A of the second light-emitting devices 22; and the first pixel openings K1 are the light-emitting regions E of the first light-emitting devices 21, and the second pixel openings K2 are the light-emitting regions E of the second light-emitting devices 22.

Due to at least one of the length and width of the light-emitting region E of the first light-emitting device 21 may be less than the size of the corresponding side edge of the light-emitting region E of the second light-emitting device 22, or both the length and width of the light-emitting region E of the first light-emitting device 21 may be equal to the size of the corresponding side edge of the light-emitting region E of the second light-emitting device 22. Therefore, a length and a width of the first pixel opening K1 may be correspondingly less than a size of a corresponding side edge of the second pixel opening K2, or both the length and the width of the first pixel opening K1 are equal to the size of the corresponding side edge of the second pixel opening K2.

In some embodiments, in the above display substrate provided by the embodiments of the present disclosure, as shown in FIG. 5 and FIG. 6, since the first pixel opening K1 defines the light-emitting region E of the first light-emitting device 21, the second pixel opening K2 defines the light-emitting region E of the second light-emitting device 22, so an area of the light-emitting material layer EL in the first light-emitting device 21 can be substantially equal to an area of the light-emitting material layer EL in the second light-emitting device 22 with the same light-emitting color. In this way, only the light-emitting material layers EL located in the first pixel opening K1 and the second pixel opening K2 serve as the light-emitting regions E, and the light-emitting material layer EL disposed on the pixel definition layer 104 does not affect the light-emitting region E. However, by setting that the area of the light-emitting material layer EL in first light-emitting device 21 can be substantially equal to the area of the area of the light-emitting material layer EL in the second light-emitting device 22 with the same light-emitting color, the fine metal mask used in the light-emitting material layer EL can be evenly stressed during the stretching process, to reduce wrinkles and sagging, reduce the risk of color mixing, and ensure high process quality.

In some embodiments, in the above-mentioned display substrate provided by the embodiments of the present disclosure, as shown in FIG. 2, FIG. 7, FIG. 8 and FIG. 10, the geometric centers O′ of first light-emitting assemblies P1 in the same one row are located at the same straight line, and the geometric centers O′ of first light-emitting assemblies P1 in the same one column are located at the same straight line, so that the gaps between the first light-emitting assemblies P1 in the row direction X and the column direction Y are both larger, which ensures that the feasibility of stretching the FMM used to fabricate the cathode patterning material layer 103 while the cathode patterning material layer 103 is arranged at the larger gap.

In some embodiments, in the above-mentioned display substrate provided by the embodiments of the present disclosure, as shown in FIG. 2, FIG. 7, FIG. 8 and FIG. 10, since the first light-emitting device 21 with different colors have different aperture ratio, the first light-emitting assemblies P1 in odd-numbered rows and the first light-emitting assemblies P1 in even-numbered rows are staggered in the column direction Y, so as to ensure that the gaps between the first light-emitting assemblies P1 are large, and balance the transmittance and display effect.

In some embodiments, in the above-mentioned display substrate provided by the embodiments of the present disclosure, as shown in FIG. 2, FIG. 7, FIG. 8 and FIG. 10, the first light-emitting assemblies P1 in all odd-numbered rows are arranged aligned in the column direction Y, and the first light-emitting assemblies P1 in all even-numbered rows are arranged aligned in the column direction Y, so that the gaps between the first light-emitting assemblies P1 in the row direction X and column direction Y are more uniform, which is beneficial to ensure that the FMM used for making the cathode patterning material layer 103 can be evenly stressed during the stretching process.

In some embodiments, in the above-mentioned display substrate provided by the embodiments of the present disclosure, as shown in FIG. 2, FIG. 7, FIG. 8 and FIG. 10, the geometric center O of the cathode patterning material layer 103 and a geometric center O′ of the first light-emitting assembly P1 located at a row where the cathode patterning material layer 103 is located are arranged at the same straight line; and the geometric center O of the cathode patterning material layer 103 and a geometric center O′ of a first light-emitting assembly P1 located at a column where the cathode patterning material layer 103 is located are located at the same straight line.

In some embodiments, in the above-mentioned display substrate provided by the embodiments of the present disclosure, as shown in FIG. 2, FIG. 7, FIG. 8 and FIG. 10, an orthographic projection of the cathode patterning material layer 103 on the substrate 101 substantially coincides with an orthographic projection of gaps between all the first light-emitting assemblies 102, so as to maximize the influence of the cathode C on the transmittance of the first display region FDC.

In some embodiments, in the above-mentioned display substrate provided by the embodiments of the present disclosure, as shown in FIG. 2, FIG. 7, FIG. 8 and FIG. 10, in any one of the gaps between the first light-emitting assemblies P1, an orthographic projection of the cathode patterning material layer 103 on the base substrate 101 is a regular shape such as a square or an ellipse. In addition, when the orthographic projection of the cathode patterning material layer 103 on the base substrate 101 is an ellipse, the influence caused by optical diffraction can be reduced, and the imaging quality and display effect can be improved.

In some embodiments, the above-mentioned display substrate provided by the embodiments of the present disclosure, as shown in FIG. 5 and FIG. 6, further includes a pixel driving circuit 105 electrically connected with an anode A of a light-emitting device. Specifically, FIG. 5 and FIG. 6 only show a driving transistor DTFT of the pixel driving circuit 105. Optionally, the pixel driving circuit 105 electrically connected with the anode A of the first light-emitting device 21 can be arranged in the second display region AA or in the bezel region, to improve the transmittance of the first display region FDC. The pixel driving circuit 105 electrically connected with the light-emitting device 22 is usually arranged in the first display region FDC.

In addition, as shown in FIG. 5 and FIG. 6, the above-mentioned display substrate provided by the embodiments of the present disclosure may further include: a buffer layer 106, a gate insulating layer 107, an interlayer dielectric layer 108, an insulating layer 109, a planarization layer 110, and an encapsulation layer 111, etc. The other essential components in the display substrate should be understood by those skilled in the art, and will not be repeated here, nor should they be used as a limitation to the present disclosure.

Based on the same inventive concept, the embodiments of the present disclosure also provide a display device, as shown in FIG. 1, which may include: a display substrate 01 and a light extraction module 02; the display substrate 01 may be the above-mentioned display substrate provided by the embodiments of the present disclosure, and the light extraction module 02 may be disposed in the first display region FDC. In some embodiments, the light extraction module 02 may be a camera module, an ambient light sensor, and the like. Since the principle of the display device for solving a problem is similar to the principle of the above-mentioned display substrate for solving a problem, the implementation of the display device provided by the embodiments of the present disclosure may refer to the above-mentioned implementation of the display substrate, and repeated descriptions will not be repeated.

In some embodiments, the display device can be any product or component with a display function, such as a mobile phone, a tablet computer, a television, a monitor, a notebook computer, a digital photo frame, a navigator, a smart watch, a fitness wristband, a personal digital assistant, etc. The display device includes but not limited to: a radio frequency unit, a network module, an audio output & input unit, a sensor, a display unit, a user input unit, an interface unit, a memory, a processor, and a power supply. In addition, those skilled in the art can understand that the above-mentioned structure does not constitute a limitation on the above-mentioned display device provided by the embodiments of the present disclosure. In other words, the above-mentioned display device provided by the embodiments of the present disclosure may include more or less components than the above components, or combinations of certain components, or different arrangements of components.

Although the preferred embodiments of the present disclosure have been described, those skilled in the art can make various changes and modifications to the embodiments of the present invention without departing from the spirit and scope of the embodiments of the present invention. In this way, if the modifications and variations of the embodiments of the present invention fall within the scope of the claims of the present invention and equivalent technologies, the present invention also intends to include these modifications and variations.

1-25. (canceled)

26. A display substrate, comprising:
a base substrate, comprising a first display region and a second display region on at least one side of the first display region; wherein transmittance of the first display region is greater than transmittance of the second display region;
a plurality of light-emitting assemblies, arranged in an array on the base substrate; wherein the plurality of light-emitting assemblies comprises:
a plurality of first light-emitting assemblies in the first display region; and
a plurality of second light-emitting assemblies in the second display region; wherein a gap between two first light-emitting assemblies that are adjacent to each other is greater than a gap between two second light-emitting assemblies that are adjacent to each other;
wherein the plurality of light-emitting assemblies comprises cathodes, and the cathodes are provided with hollow structures in the first display region, and orthographic projections of the hollow structures on the base substrate overlap with an orthographic projection of at least part of gaps between the plurality of first light-emitting assemblies; and
a cathode patterning material layer, at a light-emitting side of the plurality of light-emitting assemblies; wherein an orthographic projection of the cathode patterning material layer on the base substrate substantially coincides with the orthographic projections of the hollow structures.

27. The display substrate according to claim 26, wherein the plurality of first light-emitting assemblies comprise first light-emitting devices with at least two colors, and the plurality of second light-emitting assemblies comprise second light-emitting devices with at least two colors; wherein
the at least two colors of the first light-emitting devices are same as the at least two colors of the second light-emitting devices; and
a length of a light-emitting region of a first light-emitting device in a column direction is less than a length of a light-emitting region of a second light-emitting device with the same light-emitting color as the first light-emitting device in the column direction, and a width of the light-emitting region of the first light-emitting device in a row direction is less than or equal to a width of the light-emitting region of the second light-emitting device with the same light-emitting color as the first light-emitting device in the row direction.

28. The display substrate according to claim 27, wherein each of the plurality of light-emitting assembles comprises one first light-emitting device with a first color, two first light-emitting devices with a second color, and one first light-emitting device with a third color; wherein
a width of a light-emitting region of the first light-emitting device with the first color is substantially equal to a width of a light-emitting region of a second light-emitting device with the same light-emitting color as the first light-emitting device with the first color, and a width of a light-emitting region of the first light-emitting device with the third color is substantially equal to a width of a light-emitting region of a second light-emitting device with the same light-emitting color as the first light-emitting device with the third color; and
widths of light-emitting regions of the two first light-emitting devices with the second color are less than a width of light-emitting region of a second light-emitting device with the same light-emitting color as the two first light-emitting devices with the second color.

29. The display substrate according to claim 28, wherein geometric centers of light-emitting regions of first light-emitting devices in each of the plurality of first light-emitting assemblies are staggered in the row direction and/or the column direction.

30. The display substrate according to claim 29, wherein in the first light-emitting assembly:
the light-emitting regions of the two first light-emitting devices with the second color are staggered in the row direction and the column direction;
the light-emitting region of the first light-emitting device with the third color partially overlaps with a light-emitting region of one of the two first light-emitting devices with the second color in the row direction, and partially overlaps with a light-emitting region of the other one of the two first light-emitting devices with the second color in the column direction; and
the light-emitting region of the first light-emitting device with the first color partially overlaps with the light-emitting region of one of the two first light-emitting devices with the second color in the row direction, and is arranged in a staggered manner with the light-emitting region of the other one of the two first light-emitting devices with the second color and the light-emitting region of the first light-emitting device with the third color in the column direction.

31. The display substrate according to claim 26, wherein the plurality of first light-emitting assemblies comprise first light-emitting devices with at least two colors, and the plurality of second light-emitting assemblies comprise second light-emitting devices with at least two colors, wherein
the at least two colors of the first light-emitting devices are same as the at least two colors of the second light-emitting devices;
a length of a light-emitting region of a first light-emitting device in a column direction is less than a length of a light-emitting region of a second light-emitting device with the same light-emitting color as the first light-emitting device in the column direction, and a width of the light-emitting region of the first light-emitting device in a row direction is substantially equal to a width of the light-emitting region of the second light-emitting device with the same light-emitting color as the first light-emitting device in the row direction; or
a length of a light-emitting region of a first light-emitting device in a column direction is substantially equal to a length of a light-emitting region of a second light-emitting device with the same light-emitting color as the first light-emitting device in the column direction, and a width of the light-emitting region of the first light-emitting device in a row direction is less than a width of the light-emitting region of the second light-emitting device with the same light-emitting color as the first light-emitting device in the row direction.

32. The display substrate according to claim 31, wherein each of the plurality of light-emitting assemblies comprises one first light-emitting device with a first color, two first light-emitting devices with a second color, and one first light-emitting device with a third color; wherein
a length of a light-emitting region of the first light-emitting device with the first color is less than a length of a light-emitting region of a second light-emitting device with the same light-emitting color as the first light-emitting device with the first color; and a width of the light-emitting region of the first light-emitting device with the first color is substantially equal to a width of the light-emitting region of the second light-emitting device with the same light-emitting color as the first light-emitting device with the first color; and
lengths of light-emitting regions of the two first light-emitting devices with the second color are substantially equal to a length of a light-emitting region of a second light-emitting device with the same light-emitting color as the two first light-emitting devices with the second color, and a length of a light-emitting region of the first light-emitting device with the third color is substantially equal to a length of a light-emitting region of a second light-emitting device with the same light-emitting color as the first light-emitting device with the third color; and
widths of the light-emitting regions of the two first light-emitting devices with the second color are less than a width of the light-emitting region of the second light-emitting device with the same light-emitting color as the two first light-emitting devices with the second color, and a width of the light-emitting region of the first light-emitting device with the third color is less than a width of a light-emitting region of the second light-emitting device with the same light-emitting color as the first light-emitting device with the third color.

33. The display substrate according to claim 32, wherein, in the first light-emitting assembly:
a geometric center of the light-emitting region of the first light-emitting device with the first color and a geometric center of the light-emitting region of the first light-emitting device with the third color are located at the same straight line along the row direction, and the geometric center of the light-emitting region of the first light-emitting device with the first color and geometric centers of the light-emitting regions of the two first light-emitting devices with the second color are staggered in the row direction; and
the geometric centers of the light-emitting regions of the first light-emitting devices with the second color are located at the same straight line along the column direction, the geometric center of the light-emitting region of the first light-emitting device with the first color, the geometric centers of the light-emitting regions of the first light-emitting devices with the second color and the geometric center of the light-emitting region of the first light-emitting device with the third color are staggered in the column direction.

34. The display substrate according to claim 33, wherein in the first light-emitting assembly:
the light-emitting regions of the two first light-emitting devices with the second color are staggered in the row direction and overlaps with each other in the column direction;
the light-emitting region of the first light-emitting device with the first color, the light-emitting regions of the two first light-emitting devices with the second color and the light-emitting region of the first light-emitting device with the third color are staggered in the column direction, and the light-emitting region of the first light-emitting device with the first color is between the light-emitting regions of the two first light-emitting devices with the second color and the light-emitting region of the first light-emitting device with the third color; and
the light-emitting region of the first light-emitting device with the first color and the light-emitting region of the first light-emitting device with the third color partially overlap with the light-emitting regions of the two first light-emitting devices with the second color in the row direction.

35. The display substrate according to claim 33, wherein a width of a light-emitting material layer of the first light-emitting device with the first color in the row direction is substantially equal to a width of an anode in the row direction;
an orthographic projection of a side edge of a light-emitting material layer of the first light-emitting device with the second color adjacent to and near the light-emitting material layer of the first light-emitting device with the first color on the base substrate substantially coincides with an orthographic projection of a side edge of an anode of the first light-emitting device with the second color; and
an orthographic projection of a side edge, adjacent to and near the light-emitting material layer of the first light-emitting device with the first color, of a light-emitting material layer of the first light-emitting device with the third color on the base substrate substantially coincides with the orthographic projection of the side edge of the anode of the first light-emitting device with the second color.

36. The display substrate according to claim 33, wherein a geometric center of a light-emitting material layer of the first light-emitting device with the first color and a geometric center of a cathode patterning material layer corresponding to the first light-emitting device with the first color are located at the same straight line along the row direction.

37. The display substrate according to claim 27, wherein an area of an anode of the first light-emitting device is less than an area of an anode of the second light-emitting device with the same light-emitting color.

38. The display substrate according to claim 26, wherein the plurality of first light-emitting assemblies comprise first light-emitting devices with at least two colors, and the plurality of second light-emitting assemblies comprise second light-emitting devices with at least two colors; wherein
the at least two colors of the first light-emitting devices are same as the at least two colors of the second light-emitting devices; and
a density of the first light-emitting devices in the first display region is less than a density of the second light-emitting devices in the second display region.

39. The display substrate according to claim 38, wherein a length of a light-emitting region of a first light-emitting device in a column direction is equal to a length of a light-emitting region of a second light-emitting device with the same light-emitting color as the first light-emitting device in the column direction, and a width of the light-emitting region of the first light-emitting device in a row direction is equal to a width of the light-emitting region of the second light-emitting device with the same light-emitting color as the first light-emitting device in the row direction.

40. The display substrate according to claim 27, further comprising: a pixel definition layer between a layer where anodes of the first light-emitting devices are located and a light-emitting material layer of the first light-emitting devices; and
the pixel definition layer comprises a plurality of first pixel openings in the first display region and a plurality of second pixel openings in the second display region; wherein
the first pixel openings at least partially expose the anodes of the first light-emitting devices, and the second pixel openings at least partially expose anodes of the second light-emitting devices; and
the first pixel openings are light-emitting regions of the first light-emitting devices, and the second pixel openings are light-emitting regions of the second light-emitting devices.

41. The display substrate according to claim 26, wherein geometric centers of first light-emitting assemblies in one row are located at the same straight line, and geometric centers of first light-emitting assemblies in the same column are located at the same straight line.

42. The display substrate according to claim 41, wherein first light-emitting assemblies in odd-numbered rows and first light-emitting assemblies in even-numbered rows are arranged staggered in a column direction.

43. The display substrate according to claim 42, wherein first light-emitting assemblies in all odd-numbered rows are arranged aligned in the column direction, and first light-emitting assemblies in all even-numbered rows are arranged aligned in the column direction.

44. The display substrate according to claim 43, wherein a geometric center of a cathode patterning material layer and a geometric center of a first light-emitting assembly located at a row where the cathode patterning material layer is located are arranged at the same straight line, and the geometric center of the cathode patterning material layer and a geometric center of a first light-emitting assembly located at a column where the cathode patterning material layer is located are arranged at the same straight line.

45. A display device, comprising: a light extraction module, and the display substrate according to claim 26; wherein the light extraction module is in the first display region.
